(19) United States
(12) Patent Application Publication
(10) Pub. No.: US 2009/0207053 A1
(43) Pub. Date: Aug. 20, 2009

(54) CHARACTER INPUT APPARATUS

(75) Inventor: Sang-Chuel Lee, Anyang-si (KR)

Correspondence Address: OLIFF & BERRIDGE, PLC, P.O. BOX 320850, ALEXANDRIA, VA, 22320-4850, US

(73) Assignee: AD SEMICONDUCTOR CO., LTD., SEOUL (KR)

(21) Appl. No.: 12/310,140

(22) PCT Filed: Mar. 16, 2007
(86) PCT No.: PCT/KR2007/001300

§ 371 Date: Feb. 13, 2009

(30) Foreign Application Priority Data
Aug. 16, 2006 (KR) 2006-77062

(51) Int. Cl. H03M 11/00

(52) U.S. Cl. 341/22

(57) ABSTRACT

Disclosed herein is a character input apparatus including a keypad with a reference key and a plurality of peripheral keys surrounding the reference key, and a recognition device which recognizes characters respectively applied to the reference key and the peripheral keys to be inputted if the reference key and the peripheral keys are respectively pressed so as to perform pressing inputs and recognizes character respectively applied to directions to be inputted if the peripheral keys are respectively pressed while the reference key is pressed so as to perform directional inputs. Accordingly, it is possible to improve convenience in character input and increasing a character input speed, by reducing the number of times of pressing of keys and eliminating input inconvenience due to a “pause” function using a directional input and a U-turn reverse direction input.

### TECHNICAL FIELD

The present invention relates to a character input apparatus, and more particularly to a character input apparatus which is capable of improving convenience in character input and increasing a character input speed, by employing a directional input method.

### BACKGROUND ART

In a conventional character input method, several Korean alphabets are allocated in one key. A specific alphabet is inputted according to the number of times the key is to be pressed and a character is completed by making a pause or pressing an OK key.

FIG. 1 is a view showing a conventional character input method. Referring to FIG. 1, for example, in order to input [symbol] character keys should be pressed in orders of: key 5, key 5, key 1, key 2, key 5, key 5, pause, key 5, key 5, key 1, and key 2. At this time, if a “pause” period is short, [symbol] may be input. Accordingly, in order to input [symbol] a pause is necessarily required. Instead of the pause, an OK key may be pressed. However, since the OK key is separated away from character input keypad, it is inconvenient to press the OK key. In addition, the “pause” reduces a character input speed. For example, in order to input “abc”, an English lower case menu is selected and character keys are then pressed in orders of: key 2, pause, key 2, key 2, pause, key 2, key 2, and key 2. That is, the character keys should be pressed six times and two pause periods are required. Accordingly, it takes so much time to input a character.

### DISCLOSURE

### Technical Problem

Therefore, the present invention has been made in view of the above problems, and it is the objective of the present invention to provide a character input apparatus capable of improving convenience and increasing a character input speed, by reducing the number of times of pressing and eliminating input inconvenience due to a “pause” function at the time of character input.

### Technical Solution

In accordance with the present invention, the above and other objects can be accomplished by the provision of a character input apparatus including: a keypad with a reference key and a plurality of peripheral keys surrounding the reference key; and a recognition device which recognizes characters respectively applied to the reference key and the peripheral keys to be inputted if the reference key and the peripheral keys are respectively pressed so as to perform pressing inputs and recognizes character respectively applied to directions to be inputted if the peripheral keys are respectively pressed while the reference key is pressed so as to perform directional inputs.

Preferably, the peripheral keys may be arranged around the reference key in all directions. In this case, the recognition device may recognize [symbol] [symbol] and [symbol] to be inputted according to the directions if the directional inputs are performed.

Preferably, the peripheral keys may include a completion key, a “-” key, a “|” key and a “.” key. In this case, the recognition device may recognize [symbol] to be inputted if [symbol] is input and the “.” key is pressed so as to perform the pressing input, recognize [symbol] to be inputted if [symbol] is input and the “.” key is pressed so as to perform the pressing input, recognize [symbol] to be inputted if [symbol] is input and the “.” key is pressed so as to perform the pressing input, and recognize [symbol] to be inputted if [symbol] is input and the “.” key is pressed so as to perform the pressing input.

In addition, all the peripheral keys may be completion keys, and the recognition device may recognize [symbol] to be inputted if [symbol] is input and a U-turn reverse direction input is performed in the same direction, recognize [symbol] to be inputted if [symbol] is input and a U-turn reverse direction input is performed in the same direction, recognize [symbol] to be inputted if [symbol] is input and a U-turn reverse direction input is performed in the same direction, and recognize [symbol] to be inputted if [symbol] is input and a U-turn reverse direction input is performed in the same direction.

Preferably, the reference key may be a consonant key. In this case, the recognition device may recognize the aspiration of a consonant corresponding thereto to be inputted if the reference key is consecutively pressed twice and recognize the fortis of the consonant to be inputted if the reference key is consecutively pressed three times.

The recognition device may recognize characters respectively applied to U-turn reverse directions to be inputted if the directional inputs are respectively performed and the reference key is then pressed so as to perform U-turn reverse direction inputs.

The reference key may be arranged in plural and adjacent reference keys may share peripheral keys interposed therebetween.

In English characters, the recognition device may recognize four different alphabets to be inputted according to the directions of the directional inputs.

In accordance with an aspect of the present invention, the above and other objects can be accomplished by the provision of a character input apparatus including: a keypad with a group of a plurality of reference keys and a plurality of peripheral keys surrounding the reference keys; and a recognition device which recognizes characters respectively applied to the reference keys and the peripheral keys to be inputted if the reference keys and the peripheral keys are respectively pressed so as to perform pressing inputs and recognizes characters respectively applied to directions to be inputted if, in a state in which a reference key is pressed, other reference keys arranged in the vicinity of the reference key or the peripheral keys are pressed so as to perform directional inputs.

In the group of reference keys, reference keys may be arranged around one reference key in all directions, the peripheral keys may be arranged around the group of reference keys, and the recognition device may recognize [symbol] [symbol] and [symbol] to be inputted according to the directions if the directional inputs are performed.

The peripheral keys may include a completion key, a “-” key, a “|” key and a “.” key. In this case, the recognition device may recognize [symbol] to be inputted if [symbol] is input and the “.” key is pressed so as to perform the pressing input, recognize [symbol] to be inputted if [symbol] is input and the “.” key is pressed so as to perform the pressing input, recognize [symbol] to be inputted if [symbol] is input and the “.” key is pressed so as to perform the pressing input, and recognize [symbol] to be inputted if [symbol] is input and the “.” key is pressed so as to perform the pressing input.

In addition, all the peripheral keys may be completion keys, and the recognition device may recognize [symbol] to be inputted if [symbol] is input and a U-turn reverse direction input is performed in the same direction, recognize [symbol] to be inputted if [symbol] is input and a U-turn reverse direction input is performed in the same direction, recognize [symbol] to be inputted if [symbol] is input and a U-turn reverse direction input is performed in the same direction, and recognize [symbol] to be inputted if [symbol] is input and a U-turn reverse direction input is performed in the same direction.

In the group of reference keys, reference keys may be arranged around one reference key in all directions, the peripheral keys may be arranged around the group of reference keys, and the recognition device may recognize four different characters to be inputted according to the directions if the directional inputs are performed.

### ADVANTAGEOUS EFFECTS

As described above, according to the present invention, it is possible to provide a character input apparatus capable of improving convenience in character input and increasing a character input speed, by reducing the number of times of pressing of keys and eliminating input inconvenience due to a “pause” function using a directional input and a U-turn reverse direction input.

### DESCRIPTION OF DRAWINGS

The above and other objects, features and other advantages of the present invention will be more clearly understood from the following detailed description taken in conjunction with the accompanying drawings, in which:

FIG. 1 is a view illustrating a conventional character input method;

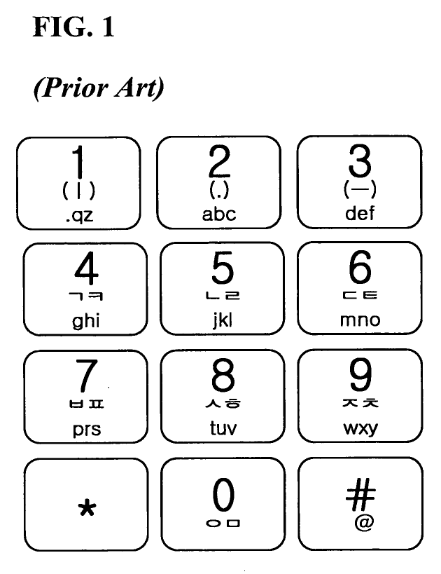

FIG. 2 is a view illustrating a character input apparatus according to a first embodiment of the present invention;

FIG. 3 is a view illustrating a method of inputting Korean characters using the character input apparatus shown in FIG. 2;

FIG. 4 is a view illustrating a case of continuously installing the character input apparatus shown in FIG. 2 in plural;

FIG. 5 is a view illustrating a method of inputting English characters using the character input apparatus shown in FIG. 2;

FIG. 6 is a view illustrating an example of inputting Korean, English and other characters using the character input apparatus according to the present invention;

FIG. 7 is a view illustrating a character input apparatus according to a second embodiment of the present invention;

FIG. 8 is a view illustrating a character input apparatus according to a third embodiment of the present invention;

FIG. 9 is a view illustrating a character input apparatus according to a fourth embodiment of the present invention; and

FIG. 10 is a view illustrating a character input apparatus according to a fifth embodiment of the present invention.

### MODE FOR INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

### First Embodiment

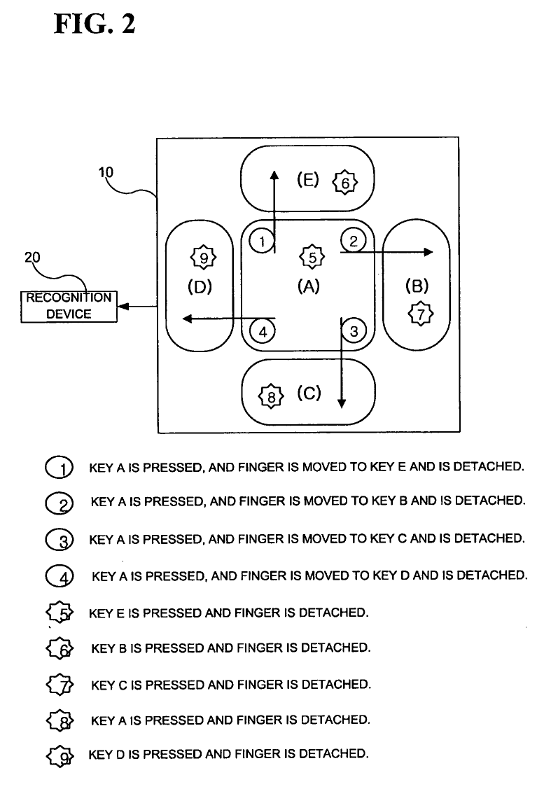

FIG. 2 is a view illustrating a character input apparatus according to a first embodiment of the present invention and more particularly, a view illustrating a directional input. Referring to FIG. 2, a keypad 10 includes a reference key A and four peripheral keys B, C, D and E surrounding the reference key A in all directions. A recognition device 20 recognizes characters respectively applied to the reference key A and the peripheral keys B, C, D and E to be inputted if the reference key A and the peripheral keys B, C, D and E are respectively pressed so as to perform pressing inputs 5, 6, 7, 8 and 9 and recognizes characters respectively applied to directions to be inputted if the peripheral keys B, C, D and E are respectively pressed while the reference key A is pressed so as to perform directional inputs 1, 2, 3 and 4. Accordingly, the recognition device 20 recognizes total nine inputs.

If the directional input 2 is performed, the reference key A is pressed and the finger is then moved so as to press the peripheral key B. At this time, since the size of the reference key A is as small as a finger of a user, the character input by the finger is accomplished in orders of A, AB and B without pause. In a case where pause is given, the recognition device 20 recognizes the directional input from the reference key A to the peripheral key B to be performed if the pause period is short and recognizes the independent pressing inputs of the reference key A and the peripheral B to be performed if the pause period is long. Accordingly, it is possible to prevent a recognition error.

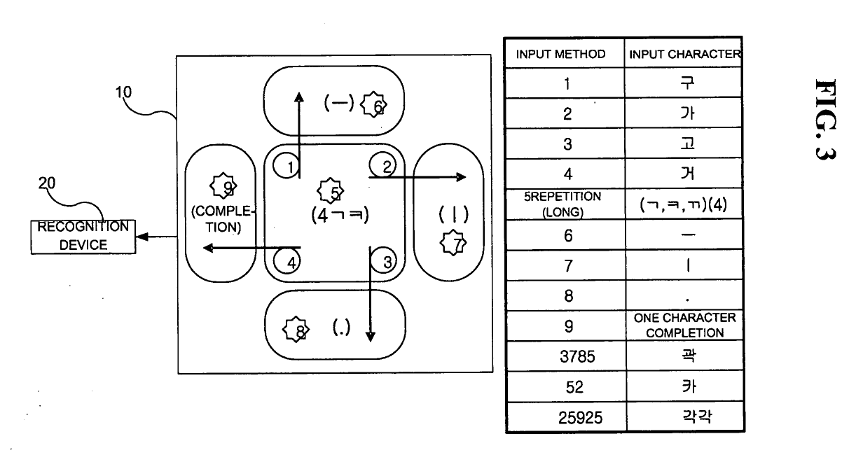

FIG. 3 is a view illustrating a method of inputting Korean characters using the character input apparatus shown in FIG. 2. Referring to FIG. 3, four peripheral keys (“-” key, “|” key, “.” key, completion key) are installed. The recognition device 20 recognizes [symbol] to be inputted if the pressing input 5 is performed, recognizes “-” to be inputted if the pressing input 6 is performed, recognizes “|” to be inputted if the pressing input 7 is performed, recognizes “.” to be inputted if the pressing input 8 is performed, recognizes the input to be completed if the pressing input 9 is performed, recognizes [symbol] to be inputted if the directional input 1 is performed, recognizes [symbol] to be inputted if the directional input 2 is performed, recognizes [symbol] to be inputted if the directional input 3 is performed, and recognizes [symbol] to be inputted if the directional input 4 is performed. In the pressing input 5, the recognition device 20 recognizes [symbol] to be inputted if pressing is performed once, recognizes [symbol] to be inputted if pressing is performed twice, recognizes [symbol] to be inputted if pressing is performed three times, and recognizes “4” to be inputted if pressing and holding are performed. The recognition device 20 recognizes [symbol] to be inputted if [symbol] is input and then the “.” key is pressed, recognizes [symbol] to be inputted if [symbol] is input and then the “.” key is pressed, recognizes [symbol] to be inputted if [symbol] is input and then the “.” key is pressed, and recognizes [symbol] to be inputted if [symbol] is input and then the “.” key is pressed. Several input examples are shown in Table of FIG. 3.

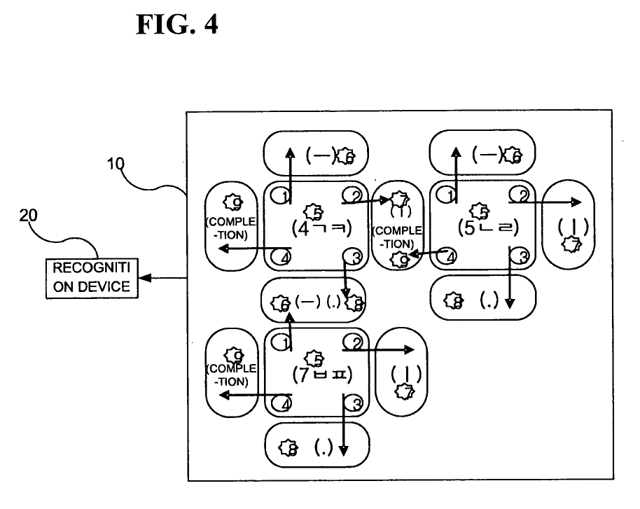

FIG. 4 is a view illustrating a case of continuously installing the character input apparatus shown in FIG. 2 in plural. As shown in FIG. 4, a plurality of reference keys [symbol] [symbol] share the peripheral keys interposed therebetween.

The pressing input 7 of the reference key 4 is equal to the pressing input 9 of the reference key 5 and the pressing input 8 of the reference key 4 is equal to the pressing input 6 of the reference key 7. If the directional input 2 and the pressing input 7 of the reference key 4 are performed in this order, [symbol] is recognized and, if the directional input 2, the pressing input 5, the pressing input 5, the pressing input 9, the pressing input 5, and the directional input 2 of the reference key 5 are performed in this order, [symbol] is recognized. If the directional input 3 and the pressing input 8 of the reference key 4 are performed in this order, [symbol] is recognized and, if the pressing input 5, the pressing input 5 and the pressing input 6 of the reference key 7 are performed in this order, [symbol] is recognized. That is, if a directional input is performed with respect to an initial consonant, a desired character can be input.

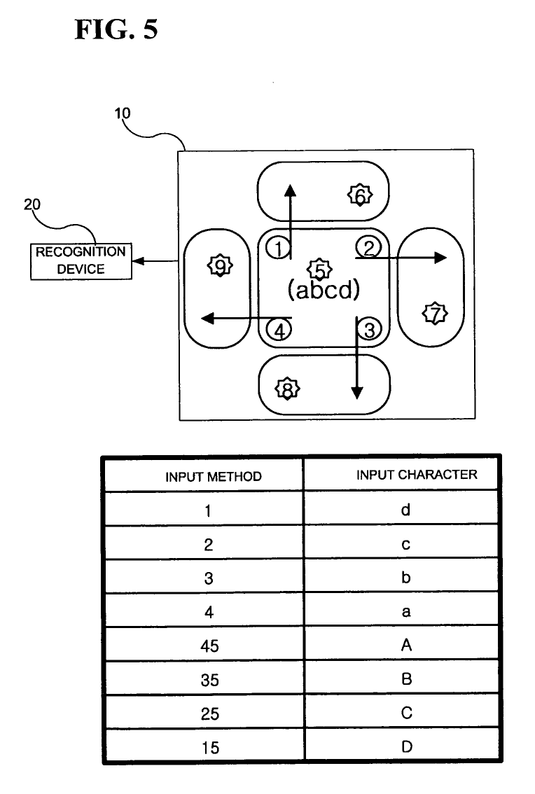

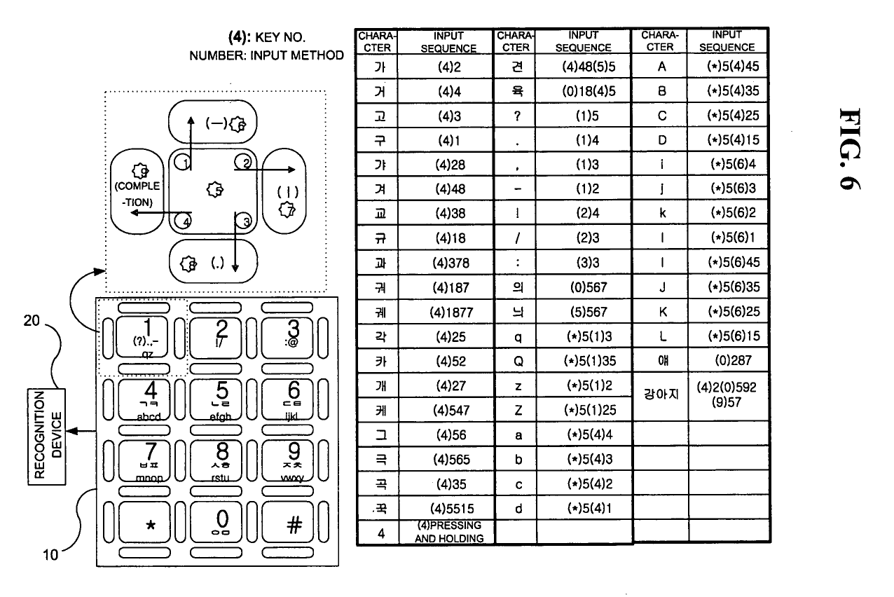

FIG. 5 is a view illustrating a method of inputting English characters using the character input apparatus shown in FIG. 2. Referring to FIG. 5, the recognition device 20 recognizes four different alphabets to be inputted according to the directions of the directional inputs and recognizes an alphabet to be inputted in capitals if the pressing input 5 of a reference key (“abcd” key) is performed. Several input examples are shown in Table of FIG. 6.

FIG. 6 is a view illustrating an example of inputting Korean, English and other characters using the character input apparatus according to the present invention.

### Second Embodiment

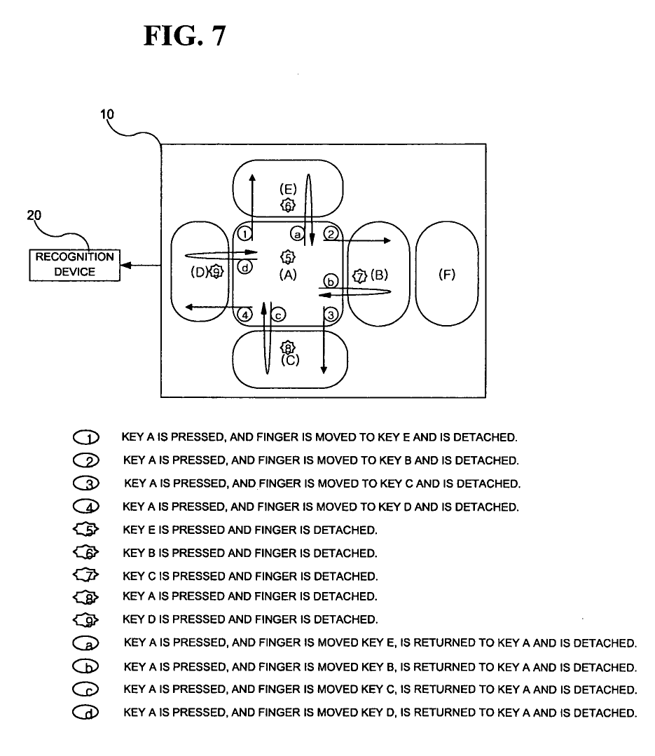

FIG. 7 is a view illustrating a character input apparatus according to a second embodiment of the present invention and more particularly, a view illustrating a U-turn reverse direction input. Referring to FIG. 7, the recognition device 20 recognizes the characters respectively applied to U-turn reverse directions to be inputted if the directional inputs 6, 7, 8 and 9 are performed and the reference key A is then pressed so as to perform U-turn reverse direction inputs a, b, c and d. Accordingly, the recognition device 20 recognizes total 13 inputs including the pressing inputs 5, 6, 7, 8 and 9, the directional inputs 1, 2, 3 and 4, and the U-turn reverse direction inputs a, b, c and d.

In order to eliminate an input error, the recognition device 20 is preferably set as follows.

First, if adjacent keys are simultaneously pressed, a key which is more strongly pressed is recognized as a valid key. Alternatively, several input sensing points such as a tact switch, a soft touch input pad or a screen pad may be provided and a key having a widest pressed area may be recognized as an input key.

Second, although the directional input is performed from the reference key A to the reference key F through the peripheral key B, it is recognized to the directional input in the same direction.

Third, although the input is performed in orders of A, B, F and B when the U-turn reverse direction input b is performed, it is recognized as the input of A, B and A. That is, although a final input point is not necessarily returned to a start point, the U-turn reverse direction input is recognized if the U-turn is performed.

### Third Embodiment

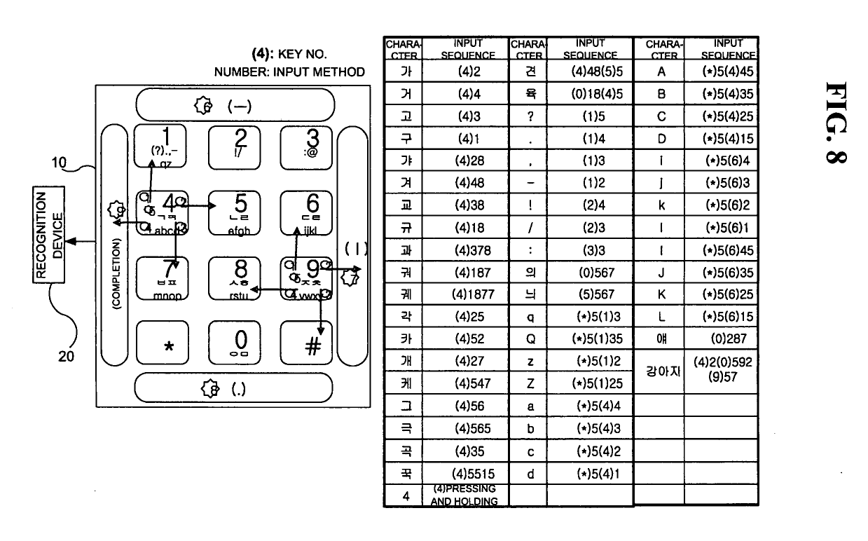

FIG. 8 is a view illustrating a character input apparatus according to a third embodiment of the present invention. Referring to FIG. 8, a group of a plurality of reference keys 1, 2, 3, 4, 5, 6, 7, 8, 9, *, 0, and # is arranged and peripheral keys (“-” key, “|” key, “.” key and completion key) are arranged around the group of reference keys in all directions.

The recognition device 20 recognizes characters respectively applied to the reference keys and the peripheral keys to be inputted if the reference keys 1, 2, 3, 4, 5, 6, 7, 8, 9, *, 0, and # and the peripheral keys (“-” key, “|” key, “.” key and completion key) are respectively pressed so as to perform the pressing inputs, and recognizes characters respectively applied to the directions to be inputted if, in a state of which a reference key is pressed, other reference keys are arranged in the vicinity of the reference key or the peripheral keys are pressed so as to perform directional inputs.

Such a configuration is preferably employed when a keypad installation area is small. The directional input 2 of the reference key 4 is performed by dragging the finger from the reference key 4 to the reference key 5. The directional input 4 of the reference key 4 is performed by dragging the finger from the reference key 4 to the leftmost side. The directional input 2 of the reference key 9 is performed by dragging the finger from the reference key 9 to the rightmost side. If the directional input 4 and the pressing input 8 of the reference key 4 are performed, [symbol] is input. Several input examples are shown in Table of FIG. 8.

### Fourth Embodiment

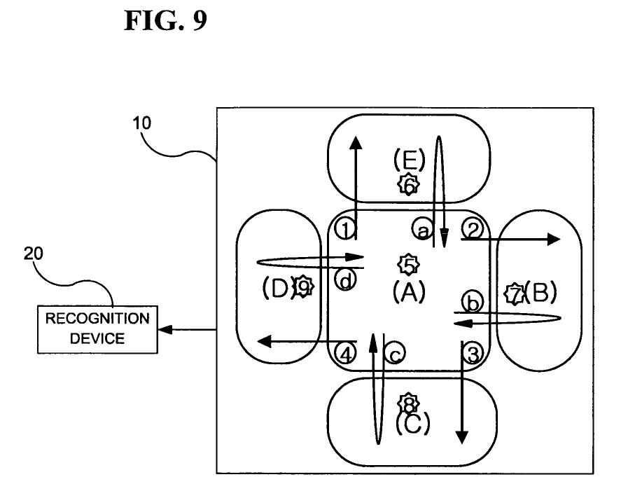

FIG. 9 is a view illustrating a character input apparatus according to a fourth embodiment of the present invention. Referring to FIG. 9, all four peripheral keys B, C, D and E arranged around a reference key A are completion keys. The recognition device 20 recognizes the directional input 1 as [symbol] the directional input 2 as [symbol] the directional input 3 as [symbol] and the directional input 4 as [symbol] If [symbol] is input and the U-turn reverse direction input a is performed in the same direction, [symbol] input is recognized, and, if [symbol] is input and the U-turn reverse direction input b is performed in the same direction, [symbol] input is recognized. If [symbol] is input and the U-turn reverse direction input c is performed in the same direction, [symbol] input is recognized, and, if [symbol] is input and the U-turn reverse direction input d is performed in the same direction, [symbol] input is recognized.

### Fifth Embodiment

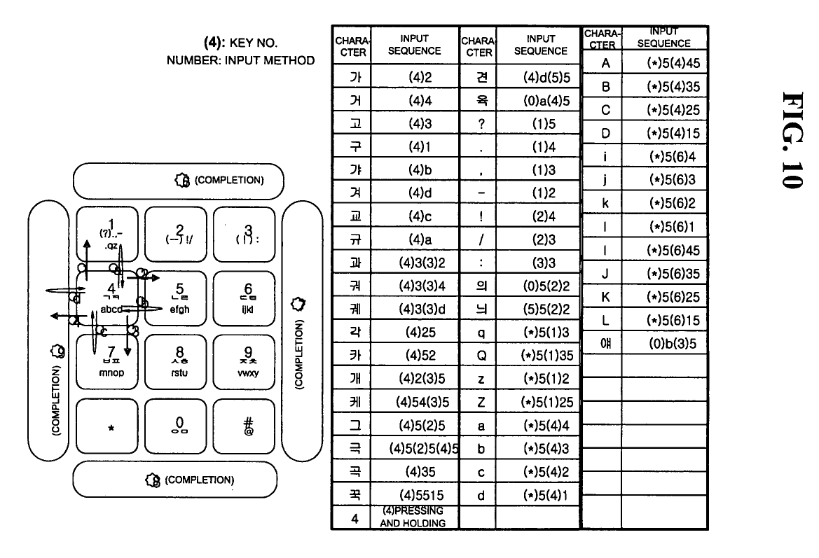

FIG. 10 is a view illustrating a character input apparatus according to a fifth embodiment of the present invention. Referring to FIG. 10, similar to the third embodiment shown in FIG. 8, a group of a plurality of reference keys 1, 2, 3, 4, 5, 6, 7, 8, 9, *, 0 and # is arranged. However, the fifth embodiment is different from the third embodiment in that all the peripheral keys arranged around the group of reference keys are completion keys instead of the “-” key, the “|” key, and the “.” key. [symbol] are input by the U-turn reverse direction inputs. If the input 5 of the reference key 2 is performed, “-” is input, and, if the input 2 of the reference key 2 is performed, [symbol] is input. If the input 5 of the reference key 3 is performed, “|” is input, and, if the input 2 of the reference key 3 is performed, [symbol] is input. if the input b of the reference key 3 is performed, [symbol] is input and, if the input d of the reference key 3 is performed, [symbol] is input. Several examples of inputting characters are shown in Table of FIG. 10.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A character input apparatus comprising:
a keypad with a reference key and a plurality of peripheral keys surrounding the reference key; and
a recognition device which recognizes characters respectively applied to the reference key and the peripheral keys to be inputted if the reference key and the peripheral keys are respectively pressed so as to perform pressing inputs and recognizes character respectively applied to directions to be inputted if the peripheral keys are respectively pressed while the reference key is pressed so as to perform directional inputs.

2. The character input apparatus according to claim 1, wherein the peripheral keys are arranged around the reference key in all directions.

3. The character input apparatus according to claim 2, wherein the recognition device recognizes [symbol] to be inputted according to the directions if the directional inputs are performed.

4. The character input apparatus according to claim 3, wherein the peripheral keys include a completion key, a “-” key, a “|” key and a “.” key.

5. The character input apparatus according to claim 4, wherein the recognition device recognizes [symbol] to be inputted if [symbol] is input and the “.” key is pressed so as to perform the pressing input, recognizes [symbol] to be inputted if [symbol] is input and the “.” key is pressed so as to perform the pressing input, recognizes [symbol] to be inputted if [symbol] is input and the “.” key is pressed so as to perform the pressing input, and recognizes [symbol] to be inputted if [symbol] is input and the “.” key is pressed so as to perform the pressing input.

6. The character input apparatus according to claim 3, wherein all the peripheral keys are completion keys, and the recognition device recognizes [symbol] to be inputted if [symbol] is input and a U-turn reverse direction input is performed in the same direction, recognizes [symbol] to be inputted if [symbol] is input and a U-turn reverse direction input is performed in the same direction, recognizes [symbol] to be inputted if [symbol] is input and a U-turn reverse direction input is performed in the same direction, and recognizes [symbol] to be inputted if [symbol] is input and a U-turn reverse direction input is performed in the same direction.

7. The character input apparatus according to claim 2, wherein the reference key is a consonant key.

8. The character input apparatus according to claim 7, wherein the recognition device recognizes the aspiration of a consonant corresponding thereto to be inputted if the reference key is consecutively pressed twice and recognizes the fortis of the consonant to be inputted if the reference key is consecutively pressed three times.

9. The character input apparatus according to claim 1, wherein the recognition device recognizes characters respectively applied to U-turn reverse directions to be inputted if the directional inputs are respectively performed and the reference key is then pressed so as to perform U-turn reverse direction inputs.

10. The character input apparatus according to claim 4, wherein the reference key is arranged in plural and adjacent reference keys share peripheral keys interposed therebetween.

11. The character input apparatus according to claim 2, wherein the recognition device recognizes four different alphabets to be inputted according to the directions of the directional inputs.

12. A character input apparatus comprising:
a keypad including a group of a plurality of reference keys and a plurality of peripheral keys surrounding the reference keys; and
a recognition device which recognizes characters respectively applied to the reference keys and the peripheral keys to be inputted if the reference keys and the peripheral keys are respectively pressed so as to perform pressing inputs and recognizes characters respectively applied to directions to be inputted if, in a state in which a reference key is pressed, other reference keys arranged in the vicinity of the reference key or the peripheral keys are pressed so as to perform directional inputs.

13. The character input apparatus according to claim 12, wherein, in the group of reference keys, reference keys are arranged around one reference key in all directions, the peripheral keys are arranged around the group of reference keys, and the recognition device recognizes [symbol] and [symbol] to be inputted according to the directions if the directional inputs are performed.

14. The character input apparatus according to claim 13, wherein the peripheral keys include a completion key, a “-” key, a “|” key and a “.” key.

15. The character input apparatus according to claim 14, wherein the recognition device recognizes [symbol] to be inputted if [symbol] is input and the “.” key is pressed so as to perform the pressing input, recognizes [symbol] to be inputted if [symbol] is input and the “.” key is pressed so as to perform the pressing input, recognizes [symbol] to be inputted if [symbol] is input and the “.” key is pressed so as to perform the pressing input, and recognizes [symbol] to be inputted if [symbol] is input and the “.” key is pressed so as to perform the pressing input.

16. The character input apparatus according to claim 13, wherein all the peripheral keys are completion keys, and the recognition device recognizes [symbol] to be inputted if [symbol] is input and a U-turn reverse direction input is performed in the same direction, recognizes [symbol] to be inputted if [symbol] is input and a U-turn reverse direction input is performed in the same direction, recognizes [symbol] to be inputted if [symbol] is input and a U-turn reverse direction input is performed in the same direction, and recognizes [symbol] to be inputted if [symbol] is input and a U-turn reverse direction input is performed in the same direction.

17. The character input apparatus according to claim 13, wherein the reference key is a consonant key.

18. The character input apparatus according to claim 17, wherein the recognition device recognizes the aspiration of a consonant corresponding thereto to be inputted if a reference key is consecutively pressed twice and recognizes the fortis of the consonant to be inputted if the reference key is consecutively pressed three times.

19. The character input apparatus according to claim 12, wherein the recognition device recognizes characters respectively applied to U-turn reverse directions to be inputted if the directional inputs are respectively performed and a reference key is then pressed so as to perform U-turn reverse direction inputs.

20. The character input apparatus according to claim 12, wherein, in the group of reference keys, reference keys are arranged around one reference key in all directions, the peripheral keys are arranged around the group of reference keys, and the recognition device recognizes four different characters to be inputted according to the directions if the directional inputs are performed.
